(19) United States
(12) Patent Application Publication
(10) Pub. No.: US 2014/0054621 A1
(43) Pub. Date: Feb. 27, 2014

(54) SEMICONDUCTOR LIGHT-EMITTING DEVICE INCLUDING TRANSPARENT PLATE WITH SLANTED SIDE SURFACE

(71) Applicant: Stanley Electric Co., Ltd., Tokyo (JP)

(72) Inventor: Toshihiro Seko, Tokyo (JP)

(73) Assignee: Stanley Electric Co., Ltd., Tokyo (JP)

(21) Appl. No.: 13/974,843

(22) Filed: Aug. 23, 2013

(30) Foreign Application Priority Data
Aug. 23, 2012 (JP) 2012-183821

(51) Int. Cl. H01L 33/50; H01L 27/15

(52) U.S. Cl. CPC H01L 33/505; H01L 27/156
USPC 257/88; 257/98

(57) ABSTRACT

In a semiconductor light-emitting device including a substrate, a semiconductor light-emitting element mounted on a top surface of the substrate, a transparent plate adapted to cover a top surface of the semiconductor light-emitting element, a wavelength-converting layer formed between a top surface of the semiconductor light-emitting element and a bottom surface of the transparent plate, and a reflective material layer surrounding all side surfaces of the semiconductor light-emitting element, the wavelength-converting layer and the transparent plate, at least one of the side surfaces of the transparent plate is slanted in an inward direction at the bottom surface of the transparent plate.

This application claims the priority benefit under 35 U.S.C. §119 to Japanese Patent Application No. JP2012-183821 filed on Aug. 23, 2012, which disclosure is hereby incorporated in its entirety by reference.

### BACKGROUND

### 1. Field

The presently disclosed subject matter relates to a semiconductor light-emitting device used as a vehicle headlamp or the like.

### 2. Description of the Related Art

Generally, a semiconductor light-emitting device is constructed by a semiconductor light-emitting element (chip) such as a light emitting diode (LED) element or a laser diode (LD) element and a wavelength-converting layer including phosphor particles for converting a part of light emitted from the semiconductor light-emitting element into wavelength-converted light with a different wavelength, thereby mixing light directly emitted from the semiconductor light-emitting element with the wavelength-converted light into white light.

In the above-mentioned semiconductor light-emitting device, the higher the density of phosphor particles in the wavelength-converting layer, the higher the efficiency of wavelength conversion. Also, the higher the efficiency of wavelength conversion, the higher the light-emitting efficiency of the device. Therefore, the wavelength-converting layer needs to be adjusted to be weight percent or more. In this case, the wavelength-converting layer needs to be adjusted to be accurately thin and uniform in order to obtain a desirable color tone.

A prior art, semiconductor light-emitting device having a high density of phosphor particles and an accurately thin and uniform wavelength-converting layor is illustrated in FIG. 8A which is a plan view and FIG. 8B which is a cross-sectional view taken along the line B-B in FIG. 1A (see: FIG. 6 of US2012/0025218A1 & JP2012-33823A).

In FIGS. 8A and 8B, reference numeral 1 designator a sub mount substrate on which a flip-chip type semiconductor light-emitting element 2 is mounted via metal bumps 2. Also, a wavelength-cenverting layer 4 including phosphor particles 4a and spacer particles 4b is formed on the semiconductor light-emitting element 2. Further, a transparent plate 5 with vertical side surfaces 5a, 5b, 5c and 5d is mounted on the wavelength-converting layer 4. Further, a frame 6 is adhered on the sub mount substrate 1 to surround the semiconductor light-emitting element 2. Furthermore, a reflective material layer 7 is provided between the semiconductor light-emitting element 2 and the frame 6, between the wavelength-oonverting layer 4 and the frame 6, and between the transparent plate 5 and the frame 6. The surface of the reflective material layer 7 linearly or curvedly extends from the top edge of the transparent plate 5 to the top edge of the frame 6.

In FIGS. 8A and 8B the thickness of the Wavelength-converting layer 4 is accurately determined by the size of the spacer particles 4b. Also, since the transparent plate 5 is in parallel with the semiconductor light-emitting element 2, the thickness of the wavelength-converting layer 4 is accurately uniform. Therefore, even when the density of the phosphor particles 4a in the wavelength-converting layer 4 is increased, the wavelength-converting layer 4 can be made accurately thin and uniform by the size of the spacer particles 4b in the wave-length-converting layer 4 and the transparent plate 5 in parallel with the semiconductor light-emitting element 2, to obtain a desirable color tone.

In FIGS. 8A and 8B the reflective marterial layer 7 is operated so as to decrease leakage light from the transparent plate 5 thereto due to its reflecting opeartion. Thus, the ratio of brightness X at the top surface (light extraction surface) of the transparent plate 5 to brightness Y at the top surface (no light extraction surface) of the reflective material layer 7, i.e., the difference between the brightness X and the brightness Y can be increased.

In the semiconductor light-emitting device of FIGS. 8A and 8B, however, since the reflectivity of the reflective material layer 7 is not 100 percent, actually 90 percent or more, the transmissivity of the reflective material layer 7 is a few percent. Therefore, as illustrated in FIG. 9, leakage light L is leaked from the transparent plate 5 into the inside of the reflective material layer 7 in accordance with the transmissivity of the reflective material layer 7, and is emitted from the vicinity of the upper edge thereof. In this case, light emitted from the vertical side surfaces 5a, 5b, 5c and 5d constitutes a circular Lambertian distribution D, and therefore, the leakage light L can be representatively defined by the magnitude of a shaded portion of the Lambertian distribution D obtained by excluding a superposed portion between the Lambertian distribution D and the transparent plate 5 from the Lambertian distribution D. Therefore, in the semiconductor light-emitting device of FIGS. 8A and 8B, the amount of the leakage light L is still large, and therefore. the brightness ratio X/Y is still small. Particularly, in a vehicle headlamp, the brightness ratio X/Y is expected to be larger than 150 or so in order to realize a clear cut-off line.

### SUMMARY

The presently disclosed subject matter seeks to solve one or more of the above- described problems.

According to the presently disclosed subject matter, in a semiconductor light-emitting device including a substrate, a semiconductor light-emitting element mounted on a top surface of the substrate, a transparent plate adapted to cover a top surface of the semiconductor light-emitting element, a wavelength-converting layer formed between a top surface of the semiconductor light-emitting element and a bottom surface of the transparent plate, and a reflective material layer surrounding all side surfaces of the semiconductor light-emitting element, the wavelength-converting layer and the transparent plate, at least one of the side surfaces of the transparent plate is slanted in an inward direction at the bottom surace of the transparent plate. Thus, since the Lamertian distribution of light emitted from the transparent plate to the reflective material layer is slanted downward, the amount of the leakage light emitted from the top surface of the reflective material layer is decreased.

According to the presenyly disclosed subject matter, since the amount of the leakage light emitted from the top surface of the reflective material at layer is decreased, the brightness ratio X/Y, i.e., the difference in brightness between X and Y can be increased.

### BRIEF DESCRIPTION OF THE DRAWINGS

The above and other advantages and features of the presently disclosed subject matter will be more apparent from the following description of certain embodiments, taken in conjunction with the accompanying drawings, as compared with the prior art, wherein:

FIG. 1A is a plan view illustrating a first embodiment of the semiconductor light-emitting device according to the presently disclosed subject matter;

FIG. 1B is a cross-sectional view taken along the line B-B in FIG. 1A;

FIG. 2 is a partial enlargement of the semiconductor light-emitting device of FIG. 1B;

FIG. 3A, 3B and 3C are cross-sectional views illustrating comparative examples of the transparent plate of FIGS. 1A and 1B;

FIG. 4 is a flowchart for explaining a method for manufacturing the semiconductor light-emitting device of FIGS. 1A and IB;

FIG. 5A is a plan view illustrating a second embodiment of the semiconductor light-emitting device according to the presently disclosed subject matter;

FIG. 5B is a cross-sectional view taken along the line B-B in FIG. 5A:

FIG. 6 is a plan view illustrating a vehicle headlamp to which the semiconductor light-emitting device of FIGS. 5A and 5B is applied;

FIG. 7 is a diagram for explaining a cut-off line obtained by the vehicle headlamp of FIG. 6;

FIG. 8A is a plan view illustrating a prior art semiconductor light-emitting device;

FIG. 8B is a cross-sectional view taken along the line B-B in FIG. 8A; and

FIG. 9 is a partial enlargement of the semiconductor light-emitting device of FIG. 8B.

### DESCRIPTION OF EXEMPLARY EMBODIMENTS

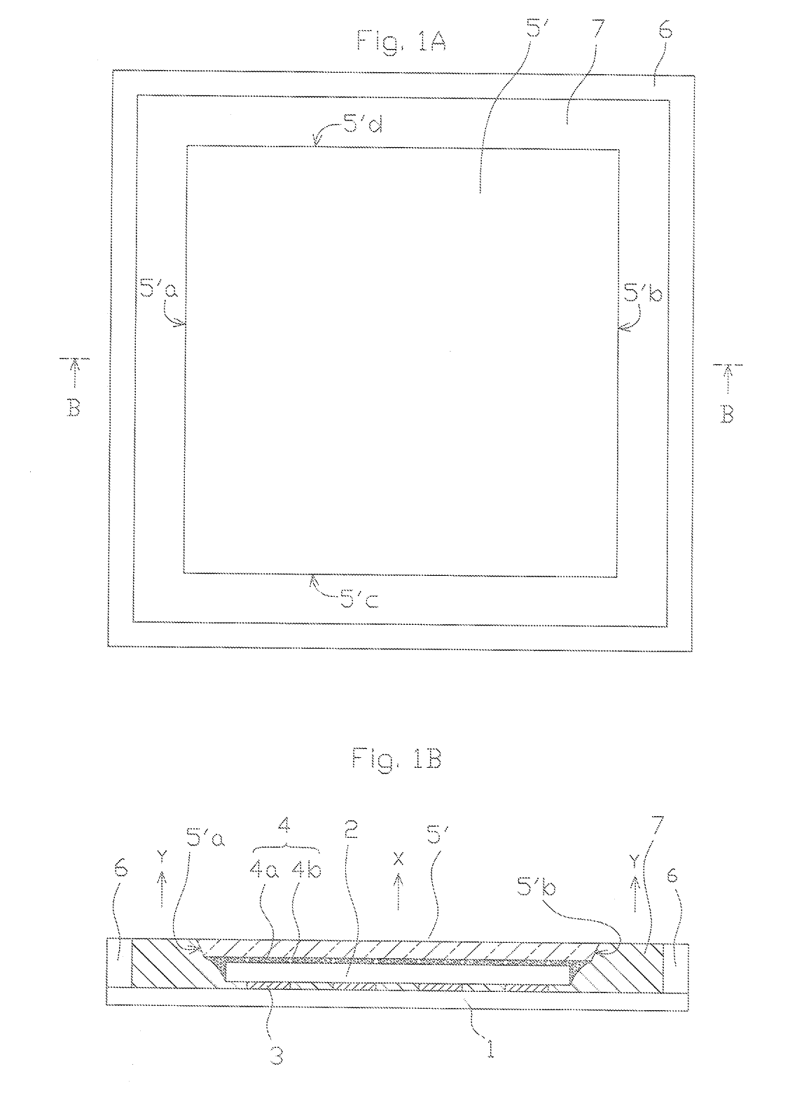

FIG. 1A, which is a plan view illustrating a first embodiment of the semiconductor light-emitting device according to the presently disclosed subject matter, and FIG. 1B is a cross-sectional view taken along the line B-B in FIG. 1A.

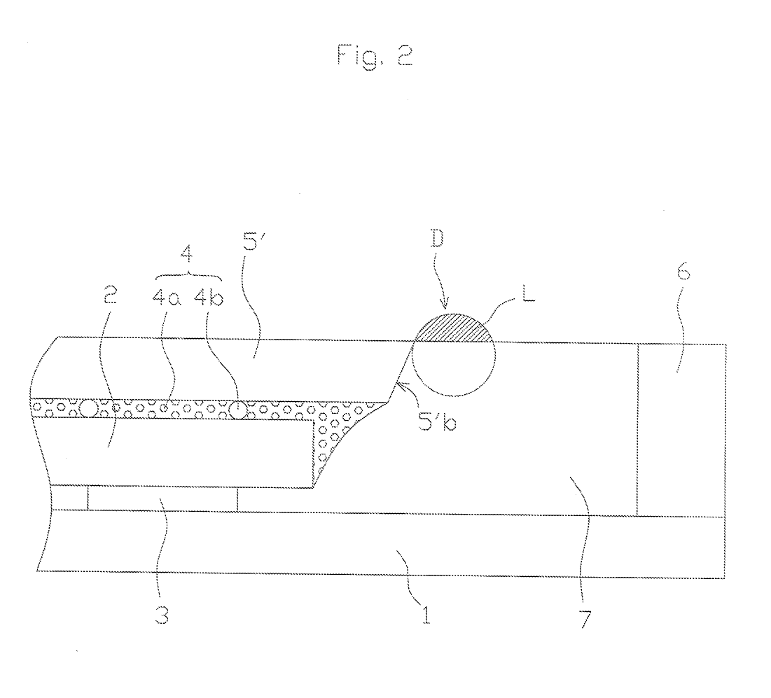

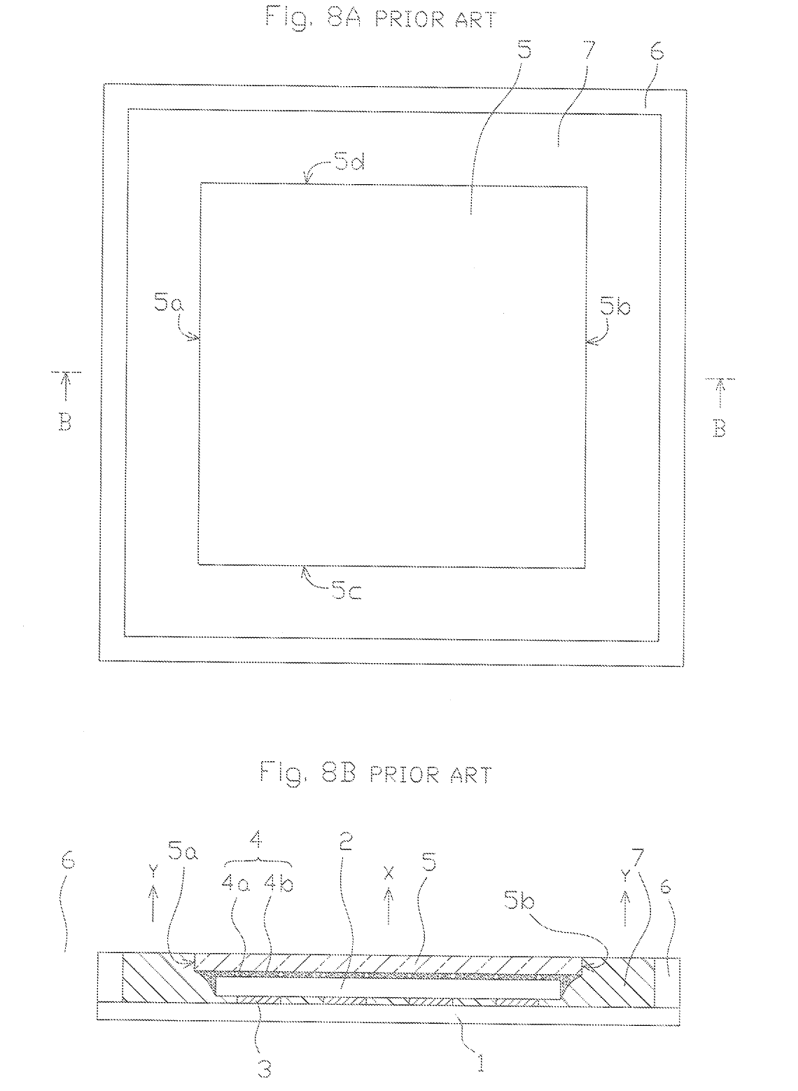

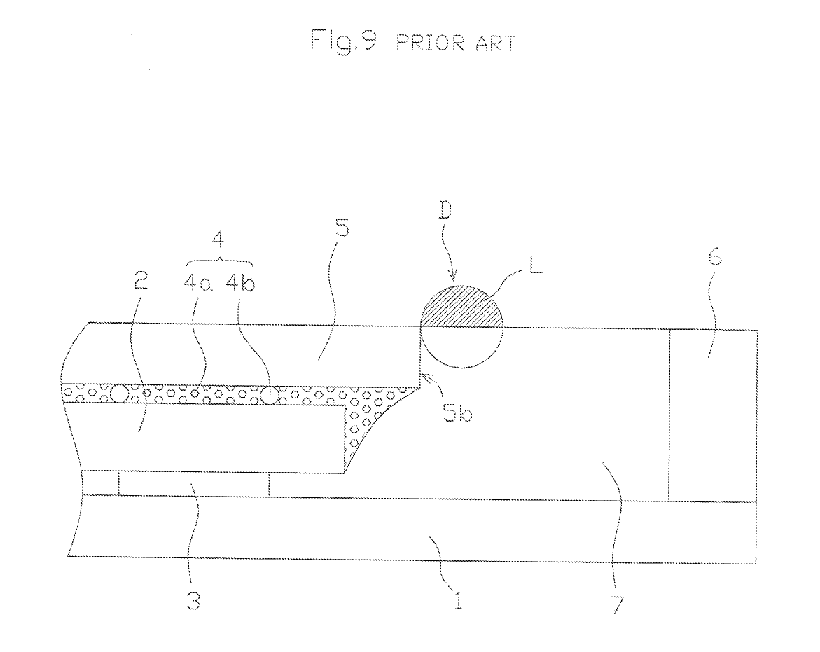

In FIGS. 1A and 1B, the transparent plate 5 of FIGS. 8A and 8B is replaced by a transparent plate 5′ with side surfaces 5′a, 5′b, 5′c and 5′d which are slanted in an inward direction at the bottom thereof. As a result, as illustrated in FIG. 2, the Lambertian distribution D of leakage light L leaked from the transparent plate 5′into the reflective material layer 7 is slanted downward, and the shaded portion of the Lambertian distribution D is decreased, so that the amount of the light emitted from the top surface of the transparent plate 5′ is decreased. Therefore, the brightness ratio X/Y can be increased.

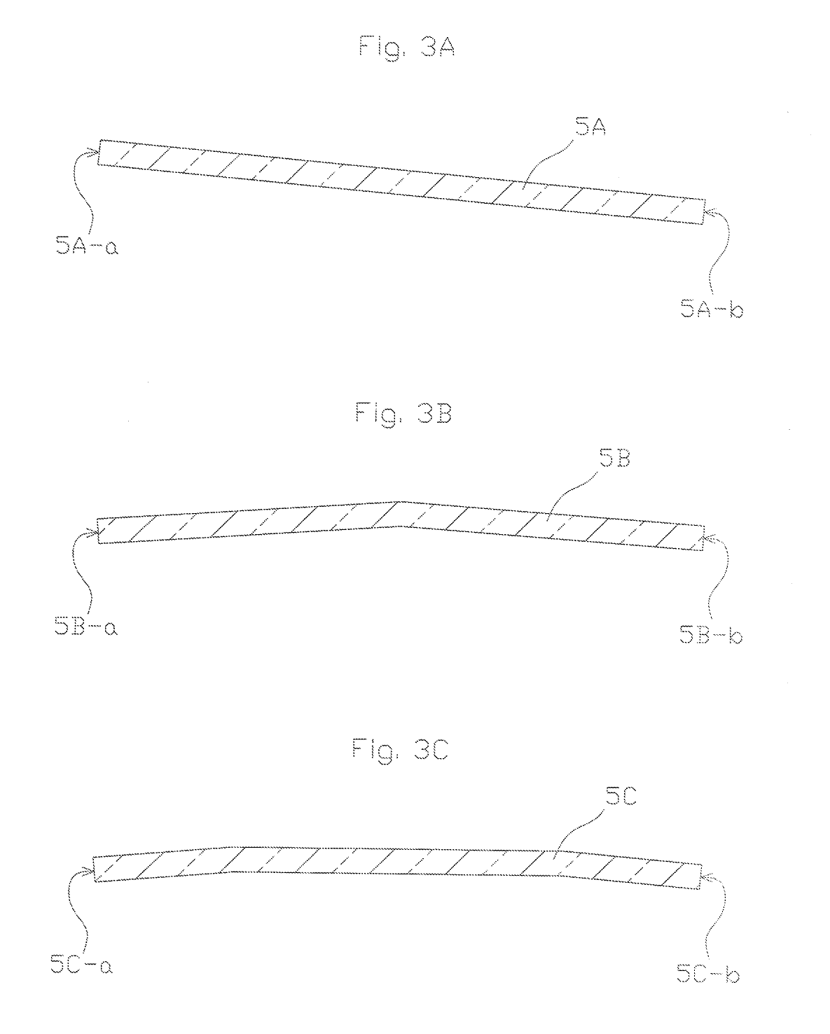

Comparative examples 5A, 5B, and 5C of the transparent plate 5′ would be considered as illustrated in FIGS. 3A, 3B and 3C, however, each of these examples has a defect in that the color tone fluctuates.

In the comparative example 5A as illustrated in FIG. 3A, a transparent plate with vertical side surfaces is slanted to realize a transparent plate 5A with slanted side surfaces 5A-a and 5A-b which are, however, slanted in opposite directions to each other. Therefore, the brightness ratio X/Y is decreased at the slanted side surface 5A-a, while the brightness ratio X/Y is increased at the slanted side surface 5A-b. Also, the thickness of the wavelength-converting layer immediately beneath the transparent plate 5A is changed by the slanted transparent plate 5A so as to change the length of optical paths within the wavelength-converting layer, thereby changing the color tone.

In the comparative example 5B as illustrated in FIG. 3B, a transparent plate with vertical side surfaces is bent at a center thereof to realize a transparent plate 5B with slanted side surfaces 5B-a and 5B-b which are both slanted inward at the bottom thereof. Therefore, the brightness ratio X/Y is increased at the slanted side surfaces 5B-a and 5A-b. However, the thickness of the wavelength-converting layer immediately beneath the transparent plate 5B is changed by the sloped transparent plate 5B so as to change the length of optical paths within the wavelength-converting layer, thereby changing the color tone.

In the comparative example 5C as illustrated in FIG. 3C, a transparent plate with vertical side surfaces is bent at two portions thereof to realize a transparent plate 5C with slanted side surfaces 5C-a and 5C-b which are both slanted inward at the bottom thereof. Therefore, the brightness ratio X/Y is increased at the slanted side surfaces 5C-a and 5C-b. However, the thickness of the wavelength-converting layer immediately beneath the transparent plate 5C is changed by the sloped portions of the transparent plate 5C so as to change the length of optical paths within the wavelength-converting layer, thereby changing the color tone. In this comparative example 5C, the color-tone-changed area is smaller than those of the comparative examples 5A and 5B.

Returning to FIG. 1A and 1B, the transparent plate 5′ with slanted side surfaces 5′a, 5′b, 5′e and 5′d which are all slanted inward at the bottom thereof is provided. Therefore, the brightness ratio X/Y is increased at the slanted side surfaces 5′a, 5′b, 5′c and 5′d. Also, the thickness of the wavelength-converting layer 4 immediately beneath the transparent plate 5′ is not changed due to the horizontal transparent plate 5′, so that the length of optical paths is uniform within the wavelength-converting layer 4, thereby unchanging the color tone.

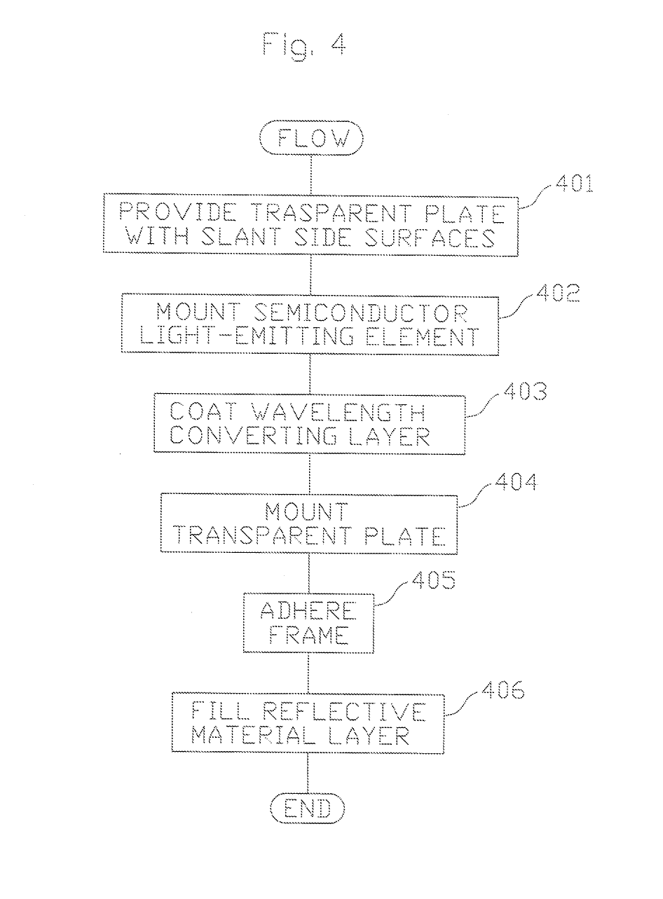

A method for manufacturing the semiconductor light-emitting device of FIG. 1A and 1B will now be explained with reference to FIG. 4.

First refferring to step 401, a transparent plate made of glass having a thickness or about 0.1 mm is prepared, and both side surfaces are cut by a blade to realize a reverse-trapezoidal cross section transparent plate 5′ having a size of about 1.2 mm×1.2 mm with slanted side surfaces 5′a, 5′b, 5′c and 5′d.

Next, referring to step 402, on about 0.1 mm thick flip-chip type semiconductor light-emitting element 2 is mounted via metal bumps 3 made of gold (Au) or the like on a sub mount substrate 1 made of aluminum nitride (AlN). In this case, the semiconductor light-emitting element 2 is connected via the metal bumps 3 to conductive patterns on the mount surface of the sub mount substrate 1.

Next, referring to step 403, a Wavelength-converting layer 4 is coated on the top surface of the semiconductor light-emitting element 2 and/or the bottom surface of the transparent plate 5′.

The wavelength-converting layer 4 includes phosphor particles 4a and spacer particles 4b dispersed in an uncured paste made of sicone resin or epoxy resin. The spacer particles 4b are made of silicon dioxide or glass which is polyhedronic or spheric. The size of the phosphor particles 4a is smaller than that of the spacer particles 4b which is 10 to 100 μm. For example, if the semiconductor light-emitting element 2 is a blue LED element, the phosphor particles 4a is made of yellow phosphor such as YAG or two phosphors of red phosphor such as CaAlSiN₃ and green phosphor such as Y₃(Ga, Al)₃O₁₂. If the semiconductor light-emitting element 2 is an ultraviolet LED element, the phosphor particles 4a are made of atleast one of yellow phosphor, red phosphor and green phosphor. The density of the phosphor particles 4a is about 13 to 90 wt percent, preferably, 50 wt percent or more to accurately determine a high light-emitting efficiency of the semiconductor light-emitting device of FIGS. 1A and 1B. Also, the size of the spacer partcles 4b is about 30 to 200 μm to accurately determine the thickness of the wavelength-converting layer 4, so that the transparent plate 5′ is in parallel with the semiconductor ligt-emitting element 2 at a post-stage step 404.

Next, referring to step 404, the transparent plate 5′ is mounted via the uncured wavelength-converting layer 4 on the semiconductor ligt-emitting element 2. Then, the uncured wavelength-converting layer 4 is cured. In this case, the wavelength-converting layer 4 extends over the side surfaces of the semiconductor light-emitting element 2 due to the surface tension of the wavelength-converting layer 4.

Next, referring to step 405, a ring-shaped frame 6 made of ceramic is adhered by adhesive (not shown) to the periphery of the top surface of the sub mount substrate 1.

Finally, referring to step 406, a reflective material layer 7 is filled between the semiconductor light-emitting element 2 and the frame 6, between the wavelength-converting layer 4 and the frame 6, and between the transparent plate 5′ and the frame 6. The reflective material layer 7 is made of silicone resin where reflective fillers of titanium oxide or zinc oxide are dispersed. The top surface of the transparent plate 5′ is planar: however, if the top surface of the transparent plate 5′ is higher than the top surface of the frame 6, the top surface of the reflective material layer 7 is curved.

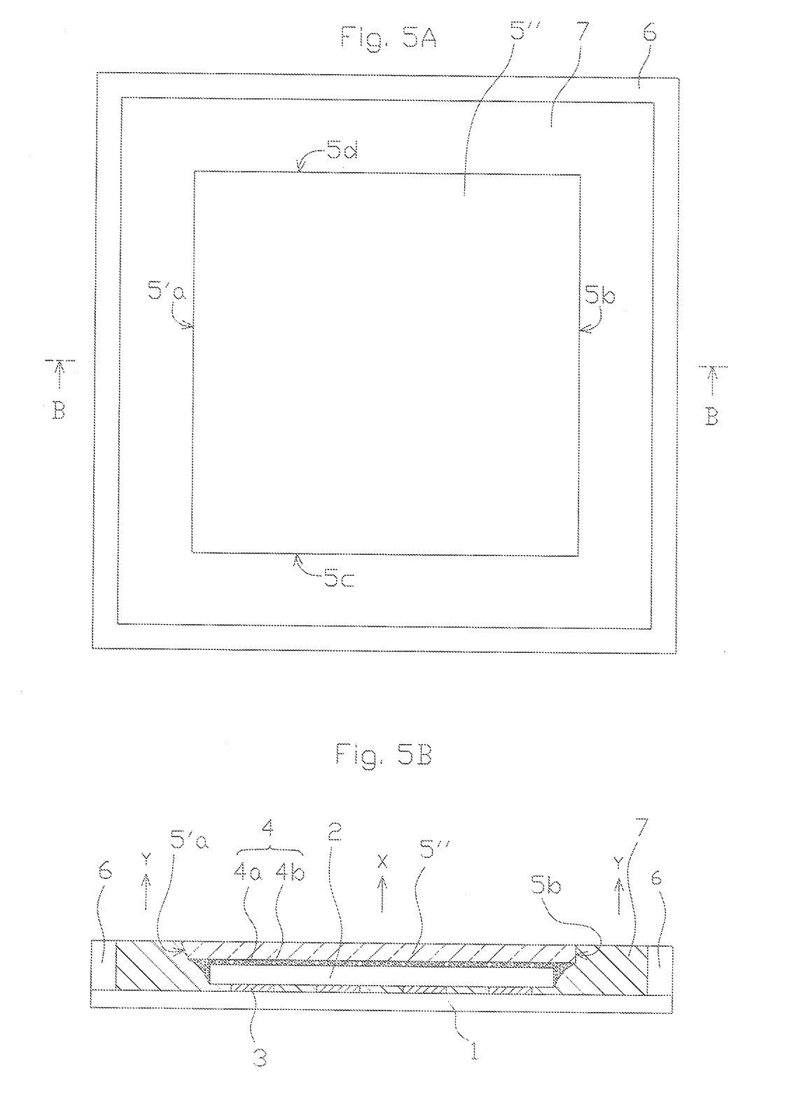

FIG. 5A, which is a plan view illustrating a second embodiment of the semiconductor light-emitting device according to the presently disclosed subject matter, and FIG. 5B is a cross-sectional view taken along the line B-B in FIG. 5A.

In FIGS. 5A and 5B the transparent plate 5 of FIGS. 8A and 8B is replaced by a transparent plate 5′ with a slanted side surface 5′a which is slanted in an inward direction at the bottom thereof and vertical side surfaces 5b, 5c and 5d. Therefore, the brightness ratio X/Y is increased at the slanted side surface 5′a, while the brightness-ratio X/Y is decreased at the vertical side surface 5b, 5c and 5d. Also, since the thickness of the wavelength-converting layer 4 immediately beneath the transparent plate 5″ is not changed by the transparent plate 5″, so that the length of optical paths is not changed within the wavelength-converting layer 4, thereby not changing the color tone.

The method for manufacturing the semiconductor light-emitting device of FIGS. 5A and 5B is the same as the method for manufacturing the semiconductor light-emitting device of FIGS. 1A and 1B as illustrated in FIG. 4 except that a one-side reverse-trapezoidal cross section transparent plate 5″ is provide at step 401.

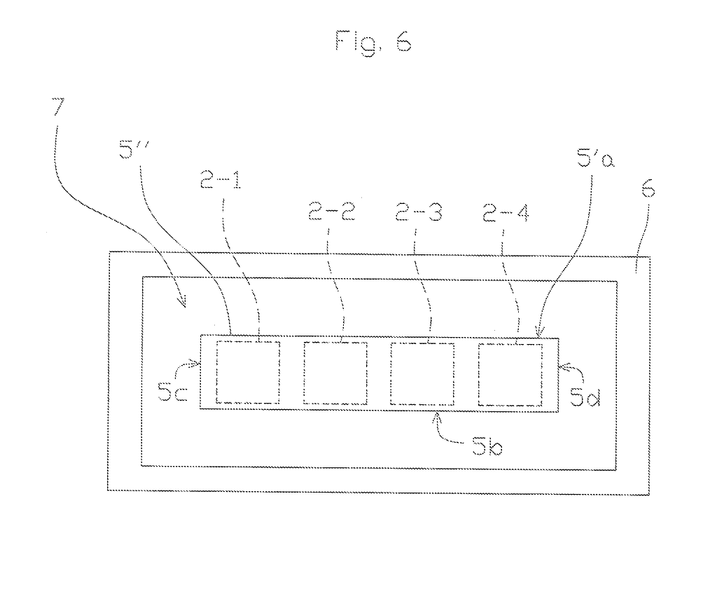

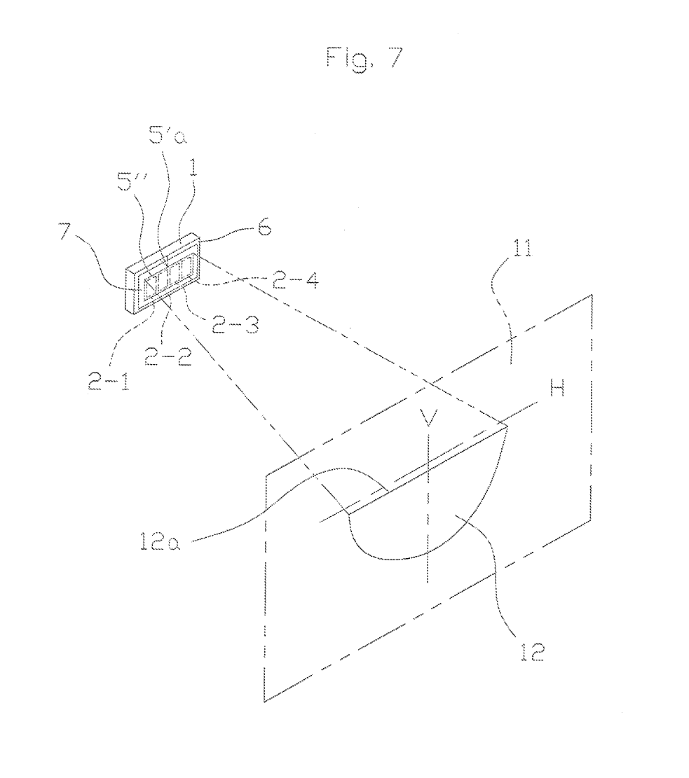

In FIG. 6, which is a plan view illustrating a vehicle headlamp to which the semiconductor light-emitting device of FIGS. 5A and 5B is applied, a plurality of semiconductor light-emitting elements, i.e., four semiconductor light-emitting elements 2-1, 2-2, 2-3 and 2-4 are serially mounted on one sub mount substrate 1 (see: FIG. 7), and one transparent plate 5″ is mounted via one wavelength-converting layer (not shown) on the semiconductor light-emitting elements 2-1, 2-2, 2-3 and 2-4. Also, one reflective material layer 7 is filled between the semiconductor light-emitting elements 2-1, 2-2, 2-3 and 2-4 and a frame 6, between the wavelength-converting layer 4 and the frame 6, and between the transparent plate 5″ and the frame 6. That is, in the transparent plate 5″, only the side surface 5′a is slanted inward at the bottom thereof, while the other side surfaces 5b, 5c and 5d are vertical.

In FIG. 7, a virtual screen 11 is vertically provided ahead of the headlamp of FIG. 6. When the headlamp is turned ON, a light distribution 12 with a clear cut-off line 12a is projected on the screen 11 due to the slanted side surface 5′a of the transparent plate 5″ where the brightness ratio X/Y is increased. In the screen 11, not at that a vertical direction V designates a height from the ground, and a cross point between the vertical, direction V and a horizontal direction H corresponds to a height of the eyes of a driver.

Also, in the above-described embodiments, although the frame 6 is provided on the periphery of the sub mount substrate 1: however, the frame 6 can be provided on a mount substrate on which the sub mount substrate 1 is also mounted.

The presently disclosed subject matter can be applied to face-up type semiconductor light-emitting elements Also, the presently disclosed subject matter can be applied to a projector, an indoor illumination apparatus, an outdoor illumination apparatus, and the like.

It will be apparent to those skilled in the art that various modifications and variations can be made in the presently disclosed subject matter without departing from the spirit or scope of the presently disclosed subject matter. Thus, it is intended that the presently disclosed subject matter covers the modifications and variations of the presently disclosed subject matter provided they come within the scope of the appended claims and their equivalents. All related or prior art references described above and in the Background section of the present specification are hereby incorporated in their entirety by reference.

1. A semiconductor light-emitting device comprising;
a substrate;
a semiconductor light-emitting element mounted on a top surface of said substrate;
a transparent plate adapted to cover a top surface of said semiconductor light-emitting element;
a wavelength-converting layer formed between a top surface of said semi conductor light-emitting element and a bottom surface of said transparent plate; and
a reflective material layer surrounding all side surfaces of said semiconductor light-emitting element, said wavelength-converting layer and said transparent plate,
at least one of the side surfaces of said transparent plate being slanted in an inward direction at the bottom surface of said transparent plate.

2. The semiconductor light-emitting device as set forth in claim 1, further comprising a frame mounted on a periphery of the top surface of said substrate,
said reflective material layer being disposed between said semiconductor light-emitting element and said frame, between said wavelength-converting layer and said frame, and between said transparent plate and said frame.

3. The semiconductor light-emitting device as set forth in claim 1, wherein said wavelength-converting layer includes phosphor particles and spacer particles, a thickness of said wavelength-converting layer being determined by a size of said spacer particles.

4. The semiconductor light-emitting device as set forth in claim 3, wherein the thickness of said wavelength-converting layer is determined so that said transparent plate is in parallel with said semiconductor light-emitting element.

5. A semiconductor light-emitting device comprising:
a substrate;
a plurality of semiconductor light-emitting elements serially mounted on a top surface of said substrate;
a transparent plate adapted to cover a top surface of said semiconductor light-emitting elements;
a wavelength-converting layer formed between a top surface of said semiconductor light-emitting elements and a bottom surface of said transparent plate; and
a reflective material layer surrounding all side surfaces of said semiconductor light-emitting elements, said wavelength-converting layer and said transparent plate,
a longer one of the side surfaces of said transparent plate being slanted in an inward direction at the bottom surface of said transparent plate while the other side surfaces of said transparent plate are vertical with respect to the bottom surface thereof.

6. The semiconductor light-emitting device as set forth in claim 5, further comprising a frame mounted on a periphery of the top surface of said substrate,
said reflective material layer being disposed between said semiconductor light-emitting element and said frame, between said wavelength-converting layer and said frame, and between said transparent plate and said frame.

7. The semiconductor light-emitting device as set forth in claim 5, wherein said wavelength-converting layer includes phosphor particles and spacer particles, a thickness of said wavelength-converting layer being determined by a size of said spacer particles.

8. The semiconductor light-emitting device as set forth in claim 7, wherein the thickness of said wavelength-converting layer is determined so that said transparent plate is in parallel with said semiconductor light-emitting elements.
